(19) United States
(12) Patent Application Publication
(10) Pub. No.: US 2025/0233068 A1
(43) Pub. Date: Jul. 17, 2025

(54) SEMICONDUCTOR DEVICE, WIRING STRUCTURE AND MANUFACTURING METHOD THEREOF

(71) Applicant: Taiwan Semiconductor Manufacturing Company, Ltd., Hsinchu (TW)

(72) Inventors: Chi-Fan Chen, Taoyuan City (TW); Wen-Hao Chen, Hsin-Chu City (TW); Hsin-Ying Ho, New Taipei City (TW); Chung-Yi Yu, Hsin-Chu (TW); Dah-Chuen Ho, Hsinchu County (TW); Zhi-Xiang Yang, Hsinchu County (TW); Fang-Chang Hsueh, Hsinchu County (TW)

(73) Assignee: Taiwan Semiconductor Manufacturing Company, Ltd., Hsinchu (TW)

(21) Appl. No.: 18/412,576

(22) Filed: Jan. 14, 2024

(51) Int. Cl. H01L 23/528; H01L 21/768; H01L 23/522; H01L 23/532

(52) U.S. Cl. CPC H01L 23/5283; H01L 21/7684; H01L 23/5226; H01L 23/53295

(57) ABSTRACT

A wiring structure includes a first dielectric structure, a metal feature, a second dielectric structure and a metal pattern. The metal feature is embedded in the first dielectric structure. The second dielectric structure is disposed above the first dielectric structure and including dummy pillars and a main portion. The metal pattern is disposed above the first dielectric and including a conductive structure electrically connected with the metal feature. The dummy pillars are embedded in the conductive structure, and the main portion is surrounding the conductive structure.

### BACKGROUND

Chemical Mechanical Polishing (CMP) is an existing surface treatment technique primarily used in microelectronics manufacturing and the semiconductor industry. It combines aspects of both mechanical grinding and chemical etching to remove surface irregularities, planarize surfaces, eliminate impurities, and enhance material quality. Typically, this process involves placing a silicon wafer or other semiconductor material on a rotating platen while a chemical slurry mixed with abrasive particles is simultaneously applied to the surface. The mechanical abrasion and chemical reactions work together to remove unwanted material. This technology finds widespread use in applications such as semiconductor wafer fabrication, chip manufacturing, and optical components, where achieving highly planar surfaces is critical.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a wiring structure in accordance with an embodiment of the present disclosure.

FIG. 1B is a cross-sectional view of the wiring structure of FIG. 1A.

FIGS. 2A to 2C are cross-sectional view of a manufacturing method of the wiring structure of FIG. 1A.

FIG. 3 is a cross-sectional view of a wiring structure in accordance with another embodiment of the present disclosure.

FIG. 4 is a cross-sectional view of a semiconductor device in accordance with an embodiment of the present disclosure.

FIG. 5 is a cross-sectional view of a semiconductor device in accordance with another embodiment of the present disclosure.

FIG. 6 is a cross-sectional view of a semiconductor device in accordance with another embodiment of the present disclosure.

FIG. 7 is a top view of a wiring structure in accordance with still another embodiment of the present disclosure.

FIG. 8 is a top view of a wiring structure in accordance with yet another embodiment of the present disclosure.

FIG. 9 is a cross-sectional view of an integrated circuit device in accordance with still another embodiment of the present disclosure.

FIG. 10 is a top view of a wiring structure in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

Chemical Mechanical Polishing (CMP) process is a technique used to create flat surfaces. In some semiconductor devices, to achieve better planarity in wiring structures (such as interconnect structures or redistribution structures), one or more CMP processes are performed during the formation of the wiring structures. Generally, the CMP process simultaneously polishes the metal pattern and the dielectric material surrounding the metal pattern. Due to the CMP process having different removal rates for metal and dielectric materials, conductive structure with large area is likely to have a curved or arc-shaped top surface after the CMP process. In the disclosed embodiments, the top surface of the conductive structure is made flatter after the CMP process by reducing the pattern density of the conductive structure within the metal pattern.

In some embodiments, the pattern density of the conductive structure is reduced by incorporating dummy pillars made of dielectric material within the conductive structure. This not only makes the surface of the conductive structure flatter after the CMP process but also reduces the metal content within the wiring structure.

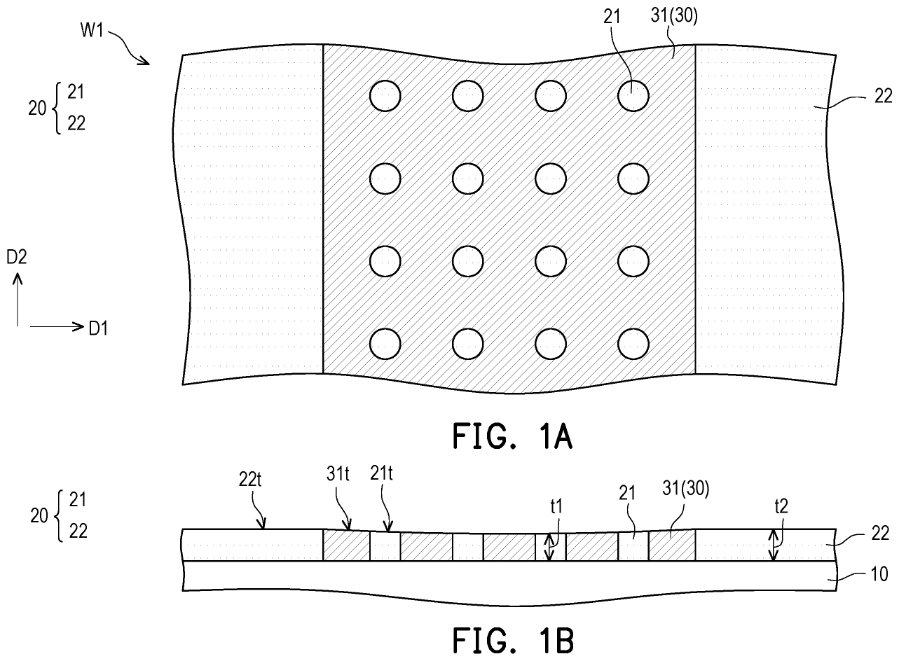

FIG. 1A is a top view of a wiring structure W1 in accordance with an embodiment of the present disclosure. FIG. 1B is a cross-sectional view of the wiring structure W1 of FIG. 1A. Referring to FIGS. 1A and 1B, the wiring structure W1 includes a first dielectric structure 10, a second dielectric structure 20 and a metal pattern 31. The first dielectric structure 10 may have a single-layer or multi-layer structure. For example, the materials of the first dielectric structure 10 may include silicon oxide, silicon nitride, silicon oxynitride, aluminum oxide, tantalum oxide, titanium oxide, hafnium oxide, or combinations thereof, or other suitable dielectric materials.

The metal pattern 30 is disposed above the first dielectric structure 10 and including a conductive structure 31. In some embodiments, the material of the metal pattern 30 may include a conductive material such as Al, Cu, W, Co, Ti, Ta, Ru, TiN, TiAl, TiAlN, TaN, TaC, NiSi, CoSi, combinations of these, or the like.

The second dielectric structure 20 is disposed above the first dielectric structure 10 and comprising a plurality of dummy pillars 21 and a main portion 22. The main portion 22 is separated from the dummy pillars 21 by the conductive structure 31. The dummy pillars 21 are embedded within the conductive structure 31, and the main portion 22 surrounds the conductive structure 31. The second dielectric structure 20 may have a single-layer or multi-layer structure. For example, the materials of the second dielectric structure 20 may include silicon oxide, silicon nitride, silicon oxynitride, aluminum oxide, tantalum oxide, titanium oxide, hafnium oxide, or combinations thereof, or other suitable dielectric materials. In some embodiments, dummy pillars 21 are constructed using materials that have a lower removal rate during the CMP process. For example, the removal rate of the dummy pillars 21 may be lower than the removal rate of the conductive structure 31.

In this embodiment, the dummy pillars 21 are configured to reduce the pattern density of conductive structure 31, thereby improving the issue of top surface erosion of conductive structure 31 after the CMP process. In some embodiments, the dummy pillars 21 may decrease the pattern density of the conductive structure 31 from over 70% to below 70%. In some embodiments, the dummy pillars 21 are completely surrounded laterally by the conductive structure 31. The separation of the dummy pillars 21 from each other is done to maintain the continuity of the conductive structure 31. This separation ensures that the conductive structure 31 remains uninterrupted and connected. Following simulations and experiments, it is observed that when the pattern density of the conductive structure 31 exceeds 50%, the pattern density has a significant impact on erosion. However, when the pattern density is reduced to less than 50%, further reduction in pattern density does not noticeably improve erosion. For instance, when the pattern density of the conductive structure 31 is reduced from 100% to 50%, it may result in a reduction of erosion by more than 90% (or even more than 95%). Further reduction in the pattern density of the conductive structure 31 may at most only reduce erosion by up to 10% (or even less than 5%). In certain embodiments, the introduction of dummy pillars 21 allows for the reduction of the pattern density of the conductive structure 31 from 100% to a range of 90%-50%. In some embodiments, the range may be, for example, 85%-50%, 80%-50%, 75%-50%, 70%-50%, 65%-50%, 60%-55%, or 55%-50%.

In some embodiments, the dummy pillars 21 have a same width. In some embodiments, the dummy pillars 21 are arranged in an array along a first direction D1 and a second direction D2. In some embodiments, the dummy pillars 21 are cylindrical pillars, but the disclosure is not limited thereto. In other embodiments, the dummy pillars 21 may be square pillars, triangular pillars, elliptical pillars, or other shapes of pillars.

In some embodiments, to reduce the variation in metal pattern density in different regions, additional dummy metal pillars may be placed within the second dielectric structure 20. For example, the metal pattern 30 may further include dummy metal pillars placed in the main portion 22. This helps to enhance the pattern density in the main portion 22 and reduce the difference between the pattern density of different regions. Consequently, it mitigates the erosion problem caused by the CMP process. However, these dummy metal pillars may have a loading effect, which, in turn, may impact the quality of signals transmitted within the wiring structure W1. In this embodiment, by reducing the pattern density of the conductive structure 31 through dummy pillars 21, the need for dummy metal pillars within the main portion 22 may be reduced or even eliminated, thereby improving the loading effect associated with dummy metal pillars.

In some embodiments, even with the presence of dummy pillars 21, the top surface of the conductive structure 31 may still experience slight erosion, resulting in a curved top surface 31t for the conductive structure 31. In certain instances, dummy pillars 21 may also exhibit curved top surfaces 21t. In some embodiments, due to erosion, the thickness t2 of the main portion 22 is larger than or equal to the thickness t1 of the dummy pillars 21. In some embodiments, the top surface 22t of the main portion 22 is flat.

In FIGS. 1A and 1B, a portion of the conductive structure 31 within the metal pattern 30 is illustrated. However, the metal pattern 30 may also include other metal structures apart from the conductive structure 31. The conductive structure 31 is configured for transmitting current/voltage signals. For example, within the first dielectric structure 10, there may be a via pattern (not shown in FIGS. 1A and 1B) that includes a plurality of conductive vias, with the conductive structure 31 electrically connected to at least one of the conductive vias, allowing electrical connection to other devices or metal patterns through the at least one of the conductive vias. In some embodiments, there may be additional metal patterns and/or conductive vias above and/or below the metal pattern 30. The wiring structure W1 may serve as an interconnect structure or redistribution structure in a semiconductor device, and the number of metal patterns within the wiring structure W1 may be adjusted based on specific requirements.

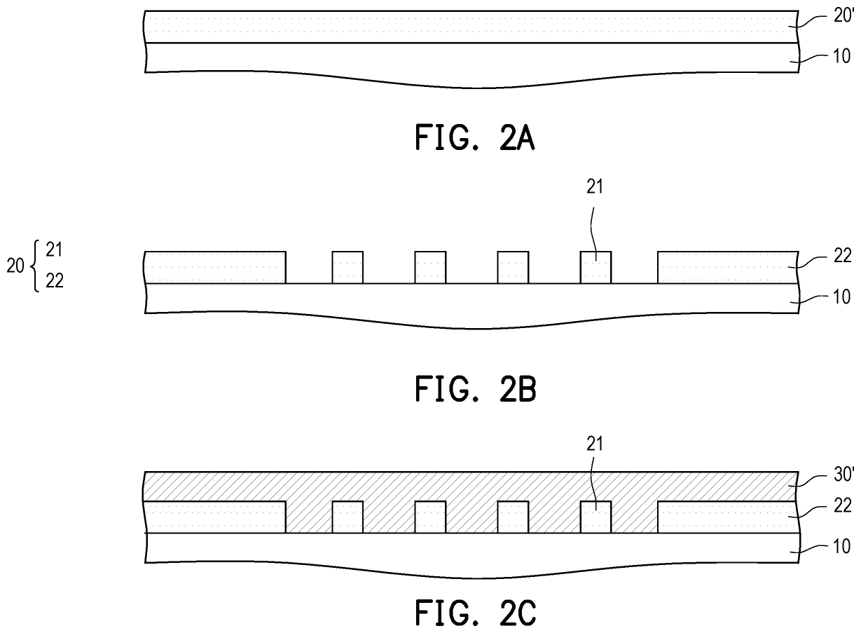

FIGS. 2A to 2C are cross-sectional view of a manufacturing method of the wiring structure 1W of FIG. 1A. Referring to FIG. 2A, a first dielectric structure 10 is formed. In some embodiments, a via pattern (not shown in FIG. 2A) including conductive vias is formed in the first dielectric structure 10.

Referring to FIGS. 2A and 2B, a second dielectric structure 20 is formed above the first dielectric structure 10. For example, insulating material 20′ is first deposited onto the first dielectric structure 10. Subsequently, a photolithography and etching process is used to pattern the aforementioned insulating material 20′, forming the second dielectric structure 20, which includes dummy pillars 21 and the main portion 22. The insulating material 20′ may be formed by any suitable processes, such as CVD, PECVD, flowable CVD (FCVD), or combinations thereof.

Referring to FIG. 2C, a metal layer 30′ is deposited above the second dielectric structure 20. The metal layer 30′ is filled between the dummy pillars 21 and covers both the dummy pillars 21 and the main portion 22. The metal layer 30′ may include a conductive material such as Al, Cu, W, Co, Ti, Ta, Ru, TiN, TiAl, TiAlN, TaN, TaC, NiSi, CoSi, combinations of these, or the like, although any suitable material may be deposited using a deposition process such as sputtering, CVD, electroplating, electroless plating, or the like.

In some embodiments, before forming the metal layer 30′, a barrier layer, a glue layer, and/or other conformal layers may be formed on the surface of the second dielectric structure 20. The barrier layer may be used to prevent the diffusion of metal elements from the metal layer 30′ into the second dielectric structure 20. The glue layer may prevent delamination issues between the metal layer 30′ and the second dielectric structure 20.

Returning to FIG. 1, a CMP process is performed on the metal layer 30′ to create the metal pattern 30. In some embodiments, the CMP process is carried out with one or more slurries (and/or abrasive particles). In certain instances, a portion of the second dielectric structure 20 is also removed during the CMP process. The removal rate of the metal layer 30′ is greater than the removal rate of the second dielectric structure 20 in the CMP process.

In certain embodiments, following the CMP process, the conductive structure 31 may exhibit a curved top surface 31t due to erosion issues. Additionally, in these embodiments, the thickness t2 of the main portion 22 is greater than or equal to the thickness t1 of the dummy pillars 21.

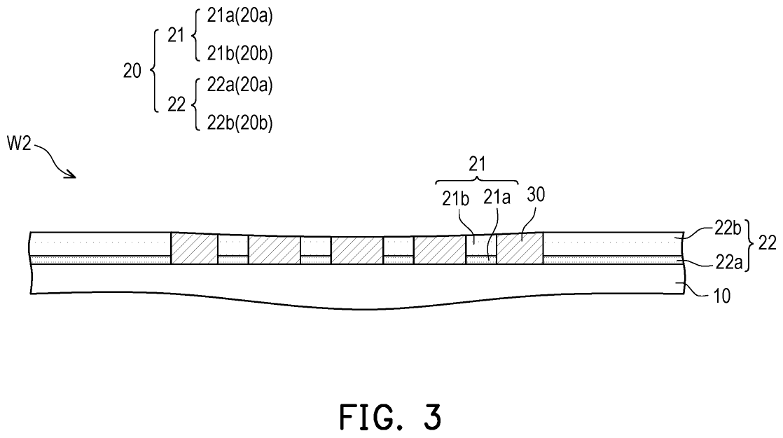

FIG. 3 is a cross-sectional view of a wiring structure W2 in accordance with another embodiment of the present disclosure. It should be noted herein that, in embodiments provided in FIG. 3, element numerals and partial content of the embodiments provided in FIG. 1A to FIG. 2C are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 3, the second dielectric structure 20 has a multilayer structure. For example, the second dielectric structure 20 includes a first layer 20a and a second layer 20b disposed on the first layer 20a. The first layer 20a, for example, is a nitride layer and includes the first portion 21a and the second portion 22a. The second layer 20b, for example, is an oxide layer and includes the first portion 21b and the second portion 22b. During the patterning process of the second dielectric structure 20, the first layer 20a may serve as an etch stop layer. Each dummy pillar 21 comprises a stack of the first portion 21a and the first portion 22a, while the main portion 22 comprises a stack of the second portion 21b and the second portion 22b.

In this embodiment, when forming openings in the second dielectric structure 20 which are used to accommodate the metal pattern 30, the openings extend through both the first layer 20a and the second layer 20b, but the disclosure is not limited thereto. In other embodiments, the openings may only penetrate the second layer 20b and stop at the first layer 20a. In such a case, the dummy pillars 21 only include the first portion 21b, and the first layer 20a beneath the dummy pillars 21, as well as the main portion 22, form a continuous structure.

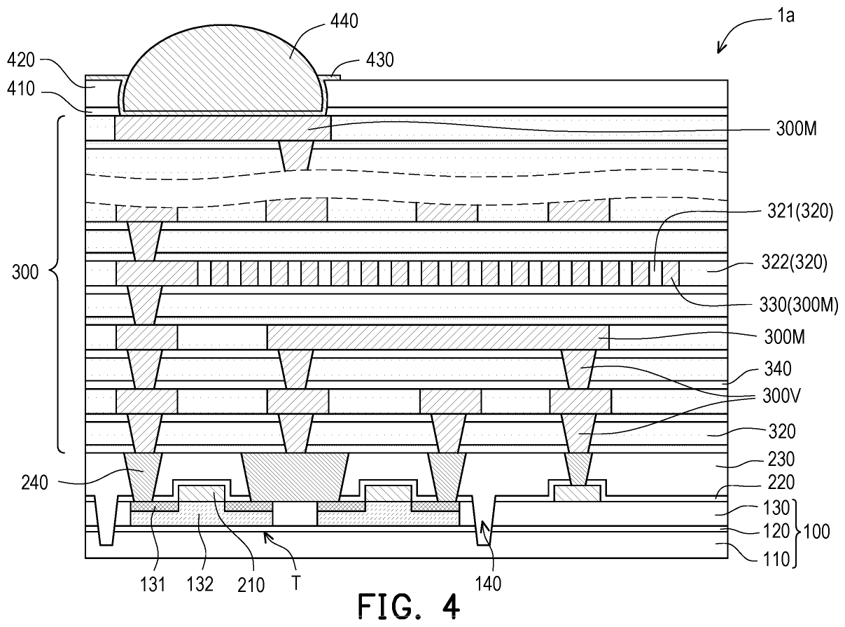

FIG. 4 is a cross-sectional view of a semiconductor device 1a in accordance with an embodiment of the present disclosure. Referring to FIG. 4, the semiconductor device 1a includes a semiconductor substrate 100, a redistribution structure 300, a first passivation layer 410, a second passivation layer 420, a metal liner 430 and a conductive terminal 440.

The substrate 100 may be a semiconductor wafer such as a silicon wafer. The substrate 100 may also include other elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium nitride, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. The substrate 100 may include an epitaxial layer. For example, the substrate 100 may be an epitaxial layer overlying a bulk semiconductor. In addition, the substrate 100 may also be semiconductor on insulator (SOI) substrate. The SOI substrate may be fabricated by a wafer bonding process, a silicon film transfer process, a separation by implantation of oxygen (SIMOX) process, other applicable methods, or a combination thereof. The substrate 100 may be an N-type substrate. The substrate 100 may be a P-type substrate.

In FIG. 4, the substrate 100 is a SOI substrate having an insulating layer 120 disposed between a handle substrate 110 and a device layer 130. In some embodiments, the handle substrate 110 may comprise a first semiconductor material such as silicon, germanium, or the like. In some embodiments, the insulating layer 120 may comprise an oxide (e.g., silicon dioxide, germanium oxide, or the like), nitride (e.g., silicon oxynitride), or the like. In some embodiments, the device layer 130 may comprise a second semiconductor material such as silicon, germanium, or the like. In some embodiments, the first semiconductor material may be a same material as the second semiconductor material.

A plurality of transistor devices T are disposed within the device layer 130 of the substrate 100. In some embodiments, the transistor devices T may be, for example, metal-oxide-semiconductor field-effect transistor (MOSFETs), a bi-polar junction transistor (BJT), or the like. In alternative embodiments, the device layer 130 may incorporate different types of transistors, including gate-all-around transistors, finFET transistors, or other types of transistors.

In some embodiments, each transistor device T comprises a gate structure 210 disposed between source/drain regions 131. The gate structure 210 may comprise a gate electrode separated from the device layer 130 by a gate dielectric layer (not shown in FIG. 4). The source/drain regions 131 have a first doping type and directly adjoin portions of the device layer 130 having a second doping type opposite the first doping type. The second doping type region between the source/drain regions 131 may be refer as a channel region 132. In various embodiments, the gate dielectric layer may be or comprise, silicon oxide, silicon nitride, silicon oxynitride, or the like. In various embodiments, the gate electrode may be or comprise, doped polysilicon, a metal, or the like. In some embodiments, the plurality of transistor devices T may be electrically isolated from one another by isolation structures 140 disposed within an upper surface of the device layer 130. In some embodiments, the isolation structures 140 may comprise one or more dielectric materials disposed within trenches in the upper surface of the device layer 130.

A contact etch stop layer (CESL) 220 is formed lining: the gate structures 210 and the source/drain regions 131. The CESL 220 may be, for example, silicon oxide, silicon nitride, or some other dielectric. Further, the CESL 220 may be formed by, for example, one or more of thermal oxidation, CVD, PVD, or ALD. In some embodiments, the CESL 220 is formed conformally. An interlayer dielectric (ILD) layer 230 is formed covering the CESL 220. The ILD layer 220 may be, for example, an oxide, PSG, a low κ dielectric, or some other dielectric. Further, the ILD layer 220 may be formed by, for example, one or more of CVD or PVD. The ILD layer 220 may fill into the trenches within an upper surface of the device layer 130, so as to form the isolation structures 140.

Conductive contacts 240 are formed in the ILD layer 220. The conductive contacts 240 includes gate contacts and source/drain contacts. The conductive contacts 240 may each include a conductive material such as Al, Cu, W, Co, Ti, Ta, Ru, TiN, TiAl, TiAlN, TaN, TaC, NiSi, CoSi, combinations of these, or the like, although any suitable material may be deposited using a deposition process such as sputtering, CVD, electroplating, electroless plating, or the like.

The redistribution structure 300 is disposed above the semiconductor substrate 100. The redistribution structure 300 comprises a plurality of metal patterns 300M and a plurality of conductive vias 300V. The metal patterns 300M may be configured to route electrical signals to and from, and/or in between, various transistor devices T of the semiconductor substrate 100. In various embodiments, the redistribution structure 300 may include a plurality of interconnect-level structures, where each interconnect-level structure may include one of dielectric structure 320 and one metal pattern 300M formed in the one of dielectric structure 320. As shown in FIG. 4, for example, the redistribution structure 300 may include a plurality of metal levels (M1, M2, M3, etc.), where each metal level may include a plurality of metal wires embedded in a dielectric structure 320. In this embodiment, each metal pattern 320M corresponds to one metal level. A first metal level (M1) may be located over the device layer 130. The conductive contacts 240 may electrically connect the devices (such as the transistor devices T) to metal wires of the first metal level (M1). Additional metal levels (M2, M3, etc.) may be located over the first metal level (M1). Each of the metal levels may be separated by at least one of dielectric structures 320. Conductive vias 300V may extend through the dielectric structure(s) 320 to electrically connect metal wire of the different metal levels.

In some embodiments, etch stop layers 340 may be separately formed on the upper surface and/or lower surface of each dielectric structure 320. In certain embodiments, the dielectric structures 320 and etch stop layers 340 consist of different materials. For example, the dielectric structures 320 may comprise oxides, while the etch stop layer 340 may comprise nitrides.

In some embodiments, the method of forming each metal level includes the following steps: first, patterning the dielectric structure 320 to create openings (or trenches) within the dielectric structure 320. Next, filling the openings (or trenches) in the dielectric structure 320 with metal material. Then, using a CMP process to remove the excess metal material that extends beyond the dielectric structure 320, leaving behind the metal pattern 300M embedded in the dielectric structure 320. Generally, in higher metal layers, there is a greater likelihood of larger metal features within the metal patterns 300M. These larger metal features tend to have higher pattern density, which may potentially lead to issues with top surface erosion after the CMP process.

To address the issue of top surface erosion, an array of dummy dielectric pillars 321 is placed within the conductive structure 330 of the metal pattern 300M to reduce the pattern density of the conductive structure 330. In this embodiment, at least one metal pattern 300M includes the conductive structure 330 along with the dummy dielectric pillars 321 situated within the conductive structure 330. The metal pattern 300M containing the conductive structure 330 may be disposed in any metal level, and the example shown in FIG. 4 is for illustrative purposes and not meant to be limiting.

In some embodiments, the dielectric structure 320 surrounding the conductive structure 330 includes the dummy dielectric pillars 321 and the main portion 322. In these embodiments, the dummy pillars 321 are distributed within the conductive structure 330 and are completely enclosed laterally by the conductive structure 330. The main portion 322 surrounds the conductive structure 330 and is separated from the dummy dielectric pillars 321 by the conductive structure 330. The structure of the conductive structure 330, dummy dielectric pillars 321, and main portion 322 as shown in FIG. 4 may be referenced to the conductive structure 31, dummy dielectric pillars 21, and main portion 22 shown in FIG. 1A and FIG. 1B.

The first passivation layer 410 and the second passivation layer 420 are disposed above the redistribution structure 300. The first passivation layer 410 and the second passivation layer 420 are patterned to form an opening exposing the topmost metal pattern 300M of the redistribution structure 300. The opening may be formed by a photolithography and/or etching processes, a laser drilling process, or the like. In some embodiments, the first passivation layer 410 and the second passivation layer 420 are formed of a polymer layer, such as an epoxy, polyimide, benzocyclobutene (BCB), polybenzoxazole (PBO), and the like, although other relatively soft, organic, dielectric materials is also used. In alternative embodiments, the first passivation layer 410 and the second passivation layer 420 is formed of a non-organic material selected from un-doped silicate glass (USG), silicon nitride, silicon oxynitride, silicon oxide, and combinations thereof.

The metal liner 430 and the conductive terminal 440 are successively formed over and electrically connected to the redistribution structure 300. In some embodiments, the metal liner 430 and the conductive terminal 440 are formed on the topmost metal pattern 300M of the redistribution structure 300, and the metal liner 430 is electrically connected to the topmost metal pattern 300M and the conductive terminal 440. In some embodiments, the metal liner 430 include at least one metallization layer including titanium (Ti), tantalum (Ta), titanium nitride (TiN), tantalum nitride (TaN), copper (Cu), copper alloys, nickel (Ni), tin (Sn), gold (Au), or combinations thereof. In some embodiments, the metal liner 430 includes at least one Ti-containing layer and at least one Cu-containing layer. In some embodiments, the conductive terminal 440 is a solder bump, a Cu bump or a metal bump including Ni or Au. In some embodiments, the conductive terminal 440 is a solder bump formed by attaching a solder ball to the metal liner 430 and then thermally reflowing the solder ball. In some embodiments, the solder bump includes a lead-free pre-solder layer, SnAg, or a solder material including alloys of tin, lead, silver, copper, nickel, bismuth, or combinations thereof. In some embodiments, the solder bump is formed by plating a solder layer with photolithography technologies followed by reflowing processes. The metal liner 430 may also be referred to as an under-bump metallization (UBM) layer.

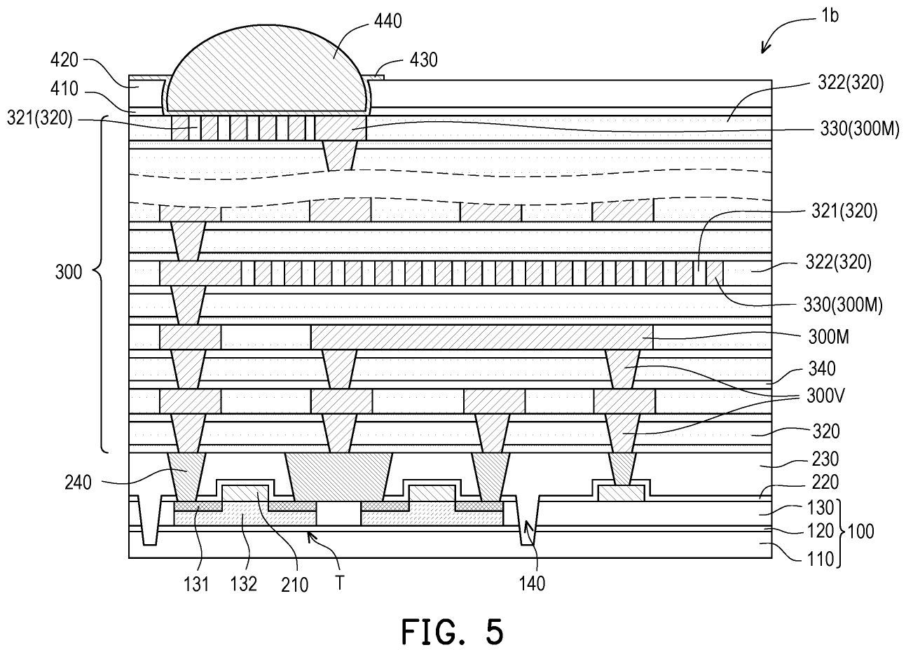

FIG. 5 is a cross-sectional view of a semiconductor device 1b in accordance with another embodiment of the present disclosure. It should be noted herein that, in embodiments provided in FIG. 5, element numerals and partial content of the embodiments provided in FIG. 4 are followed, the same or similar reference numerals being used to represent the same or similar elements, and description of the same technical content being omitted. For a description of an omitted part, reference may be made to the foregoing embodiment, and the descriptions thereof are omitted herein.

In this embodiment, as depicted in FIG. 5, the topmost metal level within the redistribution structure 300 also includes the conductive structure 330. The conductive structure 330, along with the dummy dielectric pillars 321 distributed within it, partially overlaps with the metal liner 430. The metal liner 430 is positioned on top of and in contact with the conductive structure 330, and it also contacts at least a portion of the dummy dielectric pillars 321. The conductive terminal 440 is disposed on the metal liner 430.

In this embodiment, by placing the conductive structure 330 within the topmost metal level and including the dummy dielectric pillars 321 within the conductive structure 330, the surface flatness of the topmost metal level may be improved. This improvement may lead to an increased yield for the metal liner 430 and the conductive terminal 440.

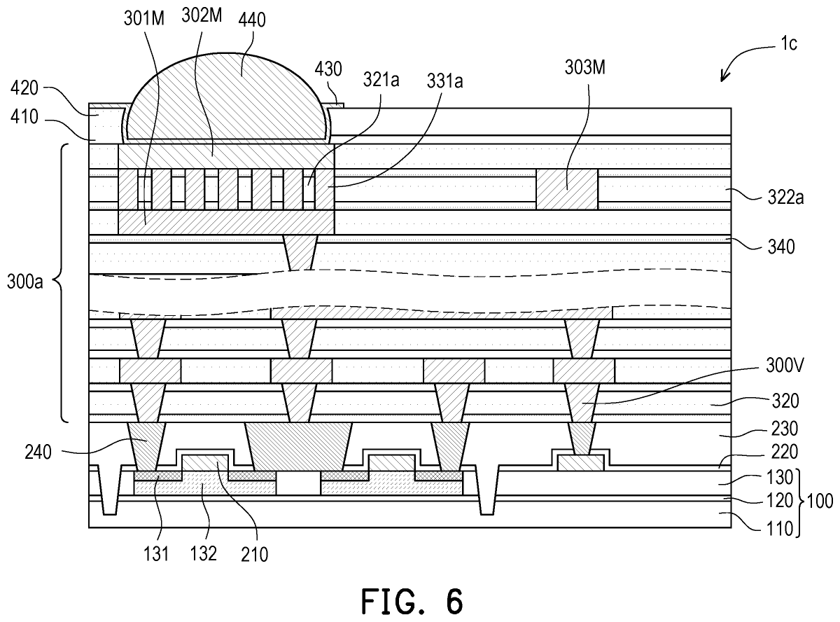

FIG. 6 is a cross-sectional view of a semiconductor device 1c in accordance with another embodiment of the present disclosure. It should be noted herein that, in embodiments provided in FIG. 6, element numerals and partial content of the embodiments provided in FIG. 4 are followed, the same or similar reference numerals being used to represent the same or similar elements, and description of the same technical content being omitted. For a description of an omitted part, reference may be made to the foregoing embodiment, and the descriptions thereof are omitted herein.

In this embodiment, as illustrated in FIG. 6, the redistribution structure 300a comprises multiple layers of metal patterns. In this embodiment, three of these metal patterns comprises a stack of a conductive feature 301M, a conductive structure 331a, and a conductive feature 302M. The conductive structure 331a is sandwiched between the conductive feature 301M and the conductive feature 302M. In this embodiment, both the conductive feature 301M and the conductive feature 302M are metal lines, but this disclosure is not limited thereto. In other embodiments, the conductive feature 301M and/or the conductive feature 302M may be metal vias.

The dummy pillars 321a are embedded within the conductive structure 331a. Each dummy pillar 321a includes a portion of the dielectric structure 320 (e.g., an oxide layer). In this embodiment, each dummy pillar 321a also includes a portion of the etch stop layers 340 (e.g., a nitride layer) located on the upper and/or bottom sides of the mentioned portion within the dielectric structure 320. In this embodiment, each dummy pillar 321a comprises two nitride layers with an oxide layer sandwiched between them, but this disclosure is not limited thereto. In other embodiments, each dummy pillar 321a may include only an oxide layer or an oxide layer paired with a nitride layer.

In this embodiment, the stack of the conductive feature 301M, the conductive structure 331a, and the conductive feature 302M is positioned beneath the conductive terminal 440 and electrically connected to it. In some embodiments, the conductive feature 302M is closer to the conductive terminal 440 compared to the conductive structure 331a. Additionally, in certain embodiments, the material of the conductive feature 302M differs from the material of the conductive feature 301M and the conductive structure 331a. For example, the material of the conductive feature 302M may include aluminum, aluminum alloys, or other suitable materials, while the materials of the conductive feature 301M and the conductive structure 331a may include copper, copper alloys, or other suitable materials.

In some embodiments, the metal pattern that includes the conductive structure 331a comprises not only the conductive structure 331a but also other metal features 303M. The metal features 303M may include metal lines and/or metal vias.

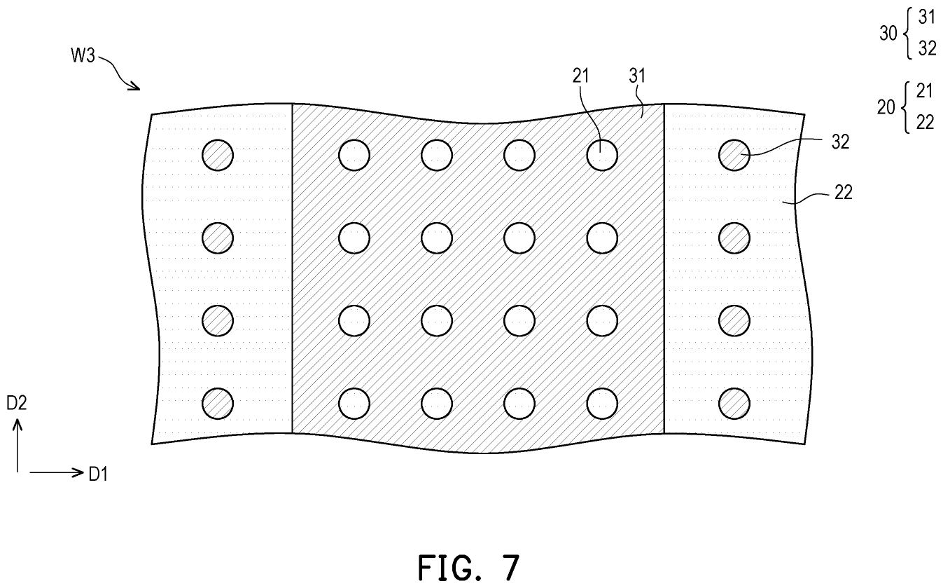

FIG. 7 is a top view of a wiring structure W3 in accordance with still another embodiment of the present disclosure. It should be noted herein that, in embodiments provided in FIG. 7, element numerals and partial content of the embodiments provided in FIGS. 1A and 1B are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 7, the metal pattern 30 of the wiring structure W3 comprises the conductive structure 31 and a plurality of dummy metal pillars 32. The dummy metal pillars 32 are embedded in the main portion 22 of the second dielectric structure 20. The dummy metal pillars 32 and the conductive structure 31 are formed simultaneously and consist of the same material. The dummy metal pillars 32 are not connected to any other metal components and exist as island-like structures. These dummy metal pillars 32 may increase the pattern density in the main portion 22, thereby avoiding issues caused by uneven distribution of metal material and may be used to strengthen the overall structure.

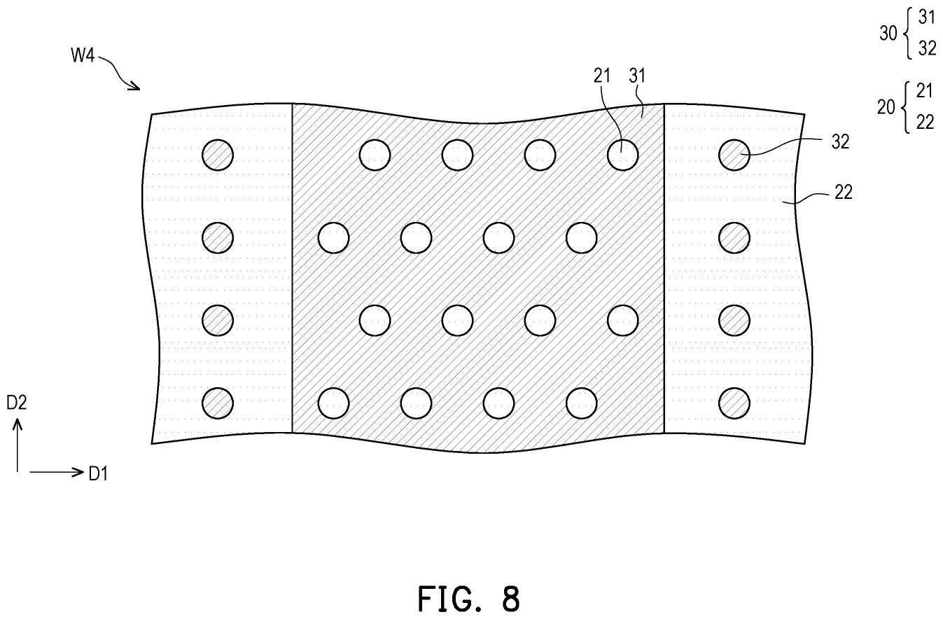

FIG. 8 is a top view of a wiring structure W4 in accordance with yet another embodiment of the present disclosure. It should be noted herein that, in embodiments provided in FIG. 8, element numerals and partial content of the embodiments provided in FIG. 7 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 8, the dummy pillars 21 in the conductive structure 31 of a wiring structure W4 are arranged in an intersecting manner. By altering the arrangement of dummy pillars 21, it is possible to reduce the probability of adjacent dummy pillars 21 becoming connected to each other due to process errors.

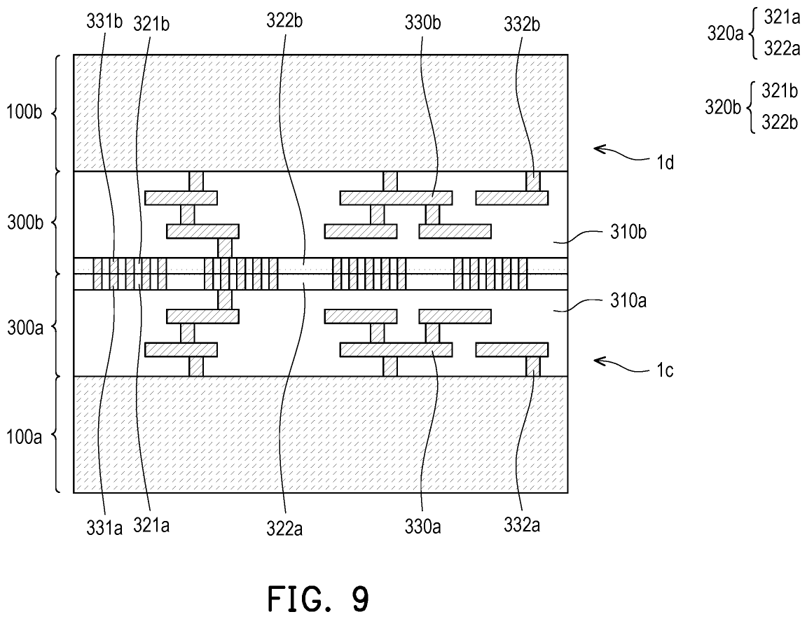

FIG. 9 is a cross-sectional view of an integrated circuit device in accordance with still another embodiment of the present disclosure. Referring to FIG. 9, the integrated circuit device includes a first semiconductor device 1c and a second semiconductor device 1d bonded to the first semiconductor device 1c.

The first semiconductor device 1c includes a substrate 100a and a back-end-of-line (BEOL) interconnect structure 300a over the substrate 100a. In some embodiments, the substrate 100a may be processed through a front-end of line (FEOL) process and have devices (e.g., CMOS field-effect transistors (FETs)) that employs a substantially monocrystalline channel material (e.g., Si) formed over thereon. The BEOL interconnect structure 300a may include metal patterns 330a and conductive vias 332a formed over the substrate 100a through a back-end of line (BEOL) process. A portion of the metal patterns 330a and conductive vias 332a are embedded in a dielectric structure 310a. The dielectric structure 310a may have a multilayer structure.

In this embodiment, the outermost metal pattern 330a of the interconnect structure 300a comprises multiple conductive structures 331a, within which an array of dummy pillars 321a is disposed. For example, on the outer side of the interconnect structure 300a, the dielectric structure 320a comprises a main portion 322a surrounding the conductive structures 331a and dummy pillars 321a embedded in the conductive structures 331a.

The second semiconductor device 1d includes a substrate 100b and a back-end-of-line (BEOL) interconnect structure 300b over the substrate 100b. In some embodiments, the substrate 100b may be processed through a front-end of line (FEOL) process and have devices (e.g., CMOS field-effect transistors (FETs)) that employs a substantially monocrystalline channel material (e.g., Si) formed over thereon. The BEOL interconnect structure 300b may include metal patterns 330b and conductive vias 332b formed over the substrate 100b through a back-end of line (BEOL) process. A portion of the metal patterns 330b and conductive vias 332b are embedded in a dielectric structure 310b. The dielectric structure 310b may have a multilayer structure.

In this embodiment, the outermost metal pattern 330b of the interconnect structure 300b comprises multiple conductive structures 331b, within which an array of dummy pillars 321b is disposed. For example, on the outer side of the interconnect structure 300b, the dielectric structure 320b comprises a main portion 322b surrounding the conductive structures 331b and dummy pillars 321b embedded in the conductive structures 331b.

In some embodiments, one or more hybrid bonding processes are performed to bond the first semiconductor device 1c and the second semiconductor device 1d. In some embodiments, the hybrid bonding process involves at least two types of bondings, including metal-to-metal (e.g., copper-to-copper) bonding and dielectric-to-dielectric bonding. For example, the conductive structures 331a of the first semiconductor device 1c are bonded to the conductive structures 331b of the second semiconductor device 1d by the metal-to-metal bonding, and the dielectric structure 320a of the first semiconductor device 1c is bonded to the dielectric structure 320b of the second semiconductor device 1d by the dielectric-to-dielectric bonding. In some embodiments, the dummy pillars 321a are bonded to the dummy pillars 321b, while the main portion 322a are bonded to the main portion 322b.

In this embodiment, due to the dummy pillars 321a and the dummy pillars 321b, a smoother surface for the conductive structures 331a and the conductive structures 331b may be achieved through the CMP process, thereby enhancing the quality of the hybrid bonding process.

In this embodiment, the hybrid bonding process is performed using the conductive structures 331a and the conductive structures 331b, but this disclosure is not limited thereto. In other embodiments, the first semiconductor device 1c and the second semiconductor device 1d each include a metal pad formed by stacking a metal feature, a conductive structure, and a metal feature (such as the conductive feature 301M, the conductive structure 331a, and the conductive feature 302M shown in FIG. 6). These metal pads may be utilized for the hybrid bonding process.

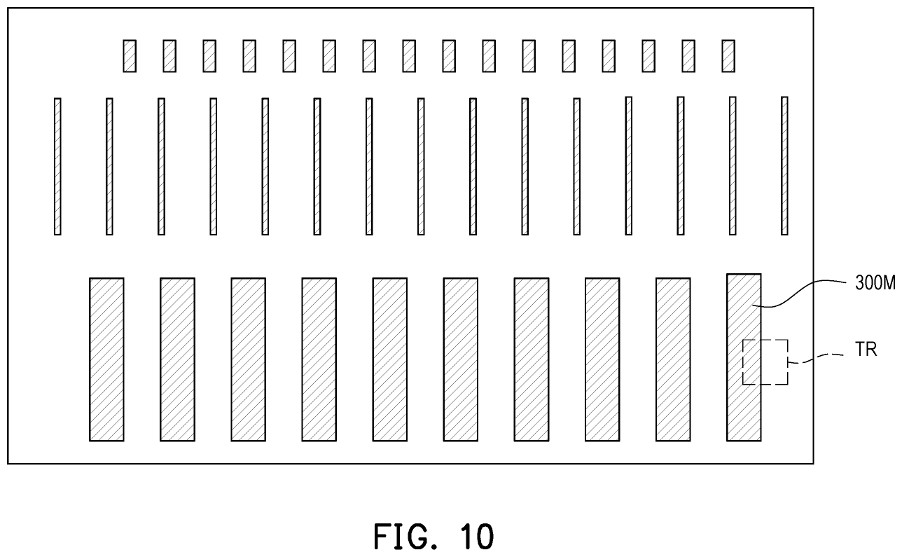

FIG. 10 is a top view of a wiring structure in accordance with various embodiments of the present disclosure. FIG. 10 is used to illustrate a method for calculating the pattern density of the metal pattern 300M. For example, the metal pattern 300M includes metal features of varying sizes and distributions in different regions. The pattern density of the metal pattern 300M may be determined through the following steps. First, define a simulated area TR, with specified dimensions; in some cases, both the length and width of the simulated area TR are set to 100 micrometers. Next, calculate the percentage of the area occupied by metal features within the simulated area TR. Measure the total area covered by metal features inside the simulated area TR, and divide this by the total area of the simulated area TR. Multiply the result by 100 to obtain the pattern density as a percentage. In some embodiments, the term “pattern density” as described herein may refer to the pattern density of local metal pattern. Specifically, from a macroscopic perspective, the metal pattern 300M may not cover the entire substrate (e.g. wafer). However, if the simulated area TR happens to select an area where all the materials are metal, the calculated pattern density may be 100%. In other words, the pattern density of the metal pattern 300M may vary in different regions.

In certain situations, for a more precise pattern density measurement, an alternative method may be used. This method involves shifting the simulated area TR by a specific distance, such as 50 micrometers, and then comparing the results with the initial calculation. This process provides a means of quantifying the extent to which metal features cover the simulated area TR, yielding a measurement of the pattern density within that area.

In some embodiments, the metal pattern 300M may have varying pattern densities in different regions. To mitigate the challenges posed by higher pattern densities within the metal pattern 300M, dummy pillars are incorporated (as illustrated by dummy pillars 21 in FIG. 1A) in the region with high pattern density. This is done to decrease the pattern density in those specific areas, for instance, by reducing it by 1% to 50%. This reduction in pattern density helps improve the quality of the CMP process.

In an embodiment of the present disclosure, a wiring structure includes a first dielectric structure, a conductive feature, a second dielectric structure and a metal pattern. The conductive feature is embedded in the first dielectric structure. The second dielectric structure is disposed above the first dielectric structure and including dummy pillars and a main portion. The metal pattern is disposed above the first dielectric and including a conductive structure electrically connected with the conductive feature. The dummy pillars are embedded in the conductive structure, and the main portion is surrounding the conductive structure.

In another embodiment of the present disclosure, a semiconductor device includes a semiconductor substrate, a redistribution structure disposed above the semiconductor substrate and dummy dielectric pillars. The redistribution structure includes metal patterns. At least one of the metal patterns includes a conductive structure electrically connected with the semiconductor substrate. The dummy dielectric pillars are dispersed in the conductive structure and completely surrounded laterally by the conductive structure.

In still another embodiment of the present disclosure, a method of manufacturing a wiring structure includes the following steps. A first dielectric structure and a conductive feature embedded in a first dielectric structure are formed. A second dielectric structure are formed above the first dielectric structure. The second dielectric structure includes dummy pillars separated from each other and a main portion separated from the dummy pillars. A metal layer is deposited above the second dielectric structure. The metal layer is filled between the plurality of dummy pillars and covers both the plurality of dummy pillars and the main portion. A chemical mechanical polishing process is performed on the metal layer to form a metal pattern including a conductive structure. The conductive structure is electrically connected with the conductive feature. The dummy pillars are embedded in the conductive structure, and the main portion is surrounding the conductive structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wiring structure, comprising:
a first dielectric structure;
a conductive feature embedded in the first dielectric structure;
a second dielectric structure, disposed above the first dielectric structure and comprising a plurality of dummy pillars and a main portion; and
a metal pattern, disposed above the first dielectric and comprising a conductive structure electrically connected with the conductive feature, wherein the plurality of dummy pillars are embedded in the conductive structure, and the main portion is surrounding the conductive structure.

2. The wiring structure of claim 1, wherein the conductive structure has a curved top surface.

3. The wiring structure of claim 1, wherein the second dielectric structure comprises a nitride layer and an oxide layer disposed above the nitride layer, wherein each dummy pillar comprises a stack of a portion of the nitride layer and a portion of the oxide layer.

4. The wiring structure of claim 1, wherein the metal pattern further comprises a plurality of dummy metal pillars embedded in the main portion.

5. The wiring structure of claim 1, wherein a thickness of the main portion is larger than or equal to a thickness of the plurality of dummy pillars.

6. The wiring structure of claim 1, wherein the plurality of dummy pillars have a same width.

7. The wiring structure of claim 1, wherein the plurality of dummy pillars are arranged in an array along a first direction and a second direction.

8. A semiconductor device, comprising:
a semiconductor substrate;
a redistribution structure disposed above the semiconductor substrate, wherein the redistribution structure comprises a plurality of metal patterns, wherein at least one of the plurality of metal patterns comprises a conductive structure electrically connected with the semiconductor substrate; and
a plurality of dummy dielectric pillars, dispersed in the conductive structure and completely surrounded laterally by the conductive structure.

9. The semiconductor device of claim 8, further comprises:
a metal liner, disposed on and in contact with the conductive structure and at least a portion of the plurality of dummy dielectric pillars; and
a conductive terminal, disposed on the metal liner.

10. The semiconductor device of claim 8, wherein each dummy dielectric pillar comprises a stack of a nitride layer and an oxide layer.

11. The semiconductor device of claim 8, wherein the conductive structure has a curved top surface.

12. The semiconductor device of claim 8, wherein the redistribution structure further comprises:
a conductive feature, wherein the conductive feature is embedded in a first dielectric layer underlying the conductive structure, and the conductive structure is electrically connected with the conductive feature, wherein the conductive feature is conductive via or a conductive line.

13. The semiconductor device of claim 8, wherein the at least one of the plurality of metal patterns further comprises a plurality of dummy metal pillars separated from the conductive structure.

14. The semiconductor device of claim 8, wherein the conductive structure is electrically connected with a transistor of the semiconductor substrate.

15. The semiconductor device of claim 8, wherein the plurality of dummy dielectric pillars have a same width.

16. A method of manufacturing a wiring structure, comprising:
forming a first dielectric structure and a conductive feature embedded in the first dielectric structure;
forming a second dielectric structure above the first dielectric structure, wherein the second dielectric structure comprises a plurality of dummy pillars separated from each other and a main portion separated from the plurality of dummy pillars;
depositing a metal layer above the second dielectric structure, wherein the metal layer is filled between the plurality of dummy pillars and covers both the plurality of dummy pillars and the main portion;
performing a chemical mechanical polishing process on the metal layer to form a metal pattern comprising a conductive structure, wherein the conductive structure is electrically connected with at least one of the conductive feature, wherein the plurality of dummy pillars are embedded in the conductive structure, and the main portion is surrounding the conductive structure.

17. The method of claim 16, wherein a portion of the second dielectric structure is also removed in the chemical mechanical polishing process, wherein a removal rate of the metal layer is higher than a removal rate of the second dielectric structure in the chemical mechanical polishing process.

18. The method of claim 16, wherein the conductive structure has a curved top surface after the chemical mechanical polishing process.

19. The method of claim 16, wherein a thickness of the main portion is larger than or equal to a thickness of the plurality of dummy pillars.

20. The method of claim 16, wherein the plurality of dummy pillars have a same width.
